(19) United States
(12) Patent Application Publication
(10) Pub. No.: US 2025/0048674 A1
(43) Pub. Date: Feb. 6, 2025

(54) METHOD FOR PRODUCING A POWER FINFET, AND POWER FINFET

(71) Applicant: Robert Bosch GmbH, Stuttgart (DE)

(72) Inventors: Daniel Krebs, Aufhausen (DE); Jens Baringhaus, Sindelfingen (DE)

(21) Appl. No.: 18/716,559

(22) PCT Filed: Dec. 14, 2022
(86) PCT No.: PCT/EP2022/085801

§ 371 Date: Jul. 8, 2024

(30) Foreign Application Priority Data
Dec. 15, 2021 (DE) 10 2021 214 432.2

(51) Int. Cl. H01L 29/78; H01L 21/3115; H01L 29/06; H01L 29/16; H01L 29/20; H01L 29/66

(52) U.S. Cl. CPC H01L 29/7813; H01L 21/31155; H01L 29/0665; H01L 29/1608; H01L 29/2003; H01L 29/66734; H01L 29/66795; H01L 29/785

(57) ABSTRACT

A method for producing a power FinFET with two-part control electrodes. The power FinFET includes a semiconductor body, which includes a first connection region, a drift layer, a channel region and a second connection region. The method includes producing trenches, which extend from the second connection region into the drift layer, the trenches being arranged substantially in parallel with one another; producing shielding regions below the trenches using an implantation process, so that a shielding region is arranged below each trench; widening the trenches using at least one etching process, so that fins are formed between the trenches, the fins having a width of less than 500 nm; and producing the two-part control electrodes, which are arranged within the trenches, so that one two-part control electrode is in each case arranged in each trench. Each two-part control electrode is electrically insulated from the shielding region below the trench.

### FIELD

The present invention relates to a method for producing a power FinFET and to a power FinFET.

### BACKGROUND INFORMATION

In power electronics, semiconductors with a wide band gap, such as SiC or GaN, are used. Typically, power MOSFETs with a vertical channel region are used.

In order to increase the breakdown voltage of such power MOSFETs, shielding regions are arranged below the trenches. Since these shielding regions are connected to the source regions, it is necessary to arrange two-part control electrodes within the trenches.

This is disadvantageous in that the trenches have to be very wide, so that the pitch dimension and the on-resistance of the power MOSFET are large.

The shielding regions, usually p-doped, are created in vertical power MOSFETs by means of a lithography mask which differs from the lithography mask for creating the trenches.

This is disadvantageous in that the two lithography masks have to be aligned with one another, which can lead to alignment errors, so an alignment allowance is provided, which increases the pitch dimension.

Alternatively, the shielding regions can be created after the trenches have been formed by means of the trench lithography mask.

This is disadvantageous in that, during implantation, part of the implantation dose is deposited into the trench side wall, whereby the p-doping of the channel region experiences an undesirable increase, which leads to a change in the threshold voltage. Another disadvantage is that the threshold voltage and the shielding voltage cannot be adjusted independently of one another as a result.

An object of the present invention is to overcome these disadvantages.

### SUMMARY

A method according to the present invention for producing a power FinFET with two-part control electrodes, wherein the power FinFET comprises a semiconductor body, which comprises a first connection region, a drift layer, a channel region and a second connection region, wherein the drift layer is arranged on the first connection region, the channel region is arranged on the drift layer, and the second connection region is arranged on the channel layer. According to an example embodiment of the present invention, the method includes producing trenches, which extend from the second connection region into the drift layer, wherein the trenches are arranged substantially in parallel with one another, and producing shielding regions below the trenches by means of an implantation process, so that a shielding region is arranged below each trench. The method furthermore includes widening the trenches by means of at least one etching process, so that fins are formed between the trenches, wherein the fins have a width of less than 500 nm, and producing the two-part control electrodes, which are arranged within the trenches, so that one two-part control electrode is in each case arranged within each trench, wherein the particular one two-part control electrode is electrically insulated from the shielding region below the trench. In other words, the shielding regions are realized by implantation into the trenches and trench side walls, wherein the deposited implantation dose in the trench side walls is removed by the widening of the trenches, so that the distances between the trenches and fins are reduced.

This is advantageous in that the threshold voltage is high and the switch-on resistance is low. Furthermore, the lateral distance of the channel relative to the shielding regions can be adjusted, wherein further lithography masks are dispensed with, so that associated alignment allowances are avoided.

In one development of the present invention, the shielding regions are produced by means of an implantation process, which in particular has implantation energies of 30 to 2700 keV.

This is advantageous in that the shielding regions are formed in the trench bottom below the gate oxide to be protected, so that a maximum shielding effect is achieved without pitch loss.

According to an example embodiment of the present invention, the power FinFET with two-part control electrodes and a semiconductor body comprises a first connection region. A drift layer is arranged on the first connection region. A channel region is arranged on the drift layer. A second connection region is arranged on the channel region. Trenches extend from the second connection region into the drift layer. A shielding region is arranged below each trench. One two-part electrode is in each case arranged within each trench, wherein the particular one two-part control electrode is electrically insulated from the shielding region below the trench. According to the present invention, fins are arranged between the trenches, wherein the fins have a width of less than 500 nm.

This is advantageous in that the pitch dimension is small and the threshold voltage is high. A further advantage is that the distances between the trenches, the so-called mesas, are narrowed sublithographically. This means that the structures are not bound to the dimensions of the lithography masks used, but can be designed to be smaller than the minimum lithography width. In addition, the shielding region and the channel are produced by means of the same lithography mask, i.e., the shielding region and the channel are aligned with one another without a mask. The pitch dimension is thus not increased by an alignment allowance.

In one development of the present invention, the shielding region has a doping concentration of at least 1E18/cm³.

This is advantageous in that high implantation doses can be cost-effectively introduced into the trench side walls at a certain height and below the trench bottom.

In one embodiment of the present invention, the semiconductor body comprises SiC.

This is advantageous in that aluminum, which is easily activatable, can be used for implantation.

In a further embodiment of the present invention, the semiconductor body comprises GaN.

This is advantageous in that the critical field strength and the electron mobility are high.

Further advantages can be found in the following description of exemplary embodiments and the rest of the disclosure herein.

### BRIEF DESCRIPTION OF THE DRAWINGS

The present invention is explained below with reference to preferred example embodiments and the figures.

FIG. 1 shows a method for producing a power FinFET with two-part control electrodes, according to an example embodiment of the present invention.

FIG. 2 shows a power FinFET with two-part control electrodes, according to an example embodiment of the present invention.

### DETAILED DESCRIPTION OF EXAMPLE EMBODIMENTS

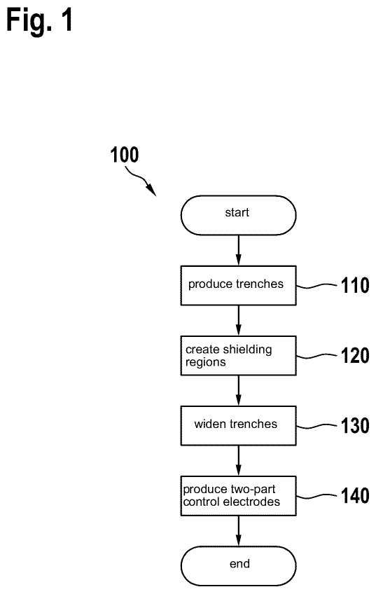

FIG. 1 shows a method 100 for producing a power FinFET with two-part control electrodes. The power FinFET comprises a semiconductor body with a first connection region, a drift layer, a channel region and a second connection region. The drift layer is arranged on the first connection region. The channel layer is arranged on the drift layer, and the second connection region is arranged on the channel layer. The method 100 starts with step 110, in which trenches are produced, which extend from the second connection region into the drift layer. A trench structuring mask is applied onto the second connection region, and the trenches are etched. The trenches are arranged substantially in parallel with one another, except for manufacturing tolerances. In a subsequent step 120, shielding regions are created below the trenches. To this end, p-doped ions are implanted with an implantation energy between 30 keV and 2700 keV into the trench structure, so that both regions below the trench bottoms and the trench side walls have implantations. These implantations can be activated in an additional step. In a subsequent step 130, the trenches are widened by means of at least one etching process. Depending on the material of the semiconductor body, etching is carried out wet-chemically or anisotropically by means of bases such as tetramethylammonium hydroxide and potassium hydroxide. In the process, the regions of the trench side walls that have implantations are removed. In this way, the distance between the trenches and fins is reduced, wherein the fins have a width of less than 500 nm. In other words, the lithographically created trenches are widened, and the mesas between the trenches are sublithographically narrowed to form fins. In a subsequent step 140, two-part control electrodes, so-called gate electrodes, are produced within the trenches. To this end, an oxide layer is applied onto the trench surface, wherein the electrode material is deposited onto the oxide layer and a further oxide layer is deposited onto the electrode material, so that the two-part control electrodes are electrically insulated from the shielding region. The opening to the shielding region and thus the division of the control electrodes into two parts is carried out by a so-called spacer process, in which only electrode material and oxide remain in each case on the side walls as a result of the deposition of electrode material and oxide and as a result of the anisotropic etching.

In a first exemplary embodiment, the semiconductor body comprises SiC. Before step 110, a nitride layer of at most 200 nm is created on a front side of the semiconductor body. The front side of the semiconductor body is represented by a top side of the second connection region. The nitride layer acts as protection for the top sides of the fins from the etching process in step 130. Between step 120 and step 130, the front side of the semiconductor body is oxidized, so that an oxide of at least 100 nm is arranged on the front side. The oxide is subsequently wet-chemically etched in step 130. Depending on the fin width to be achieved, the oxidation step and step 130 are carried out cyclically. In other words, the front side of the semiconductor body is oxidized multiple times, with an etching step taking place between the oxidation steps. The widening of the trenches thus takes place without alignment since the lateral oxidation rate exceeds the vertical oxidation rate by approximately a factor of two.

In a second exemplary embodiment, the semiconductor body comprises GaN. The etching in step 130 takes place anisotropically with TMAH or KOH.

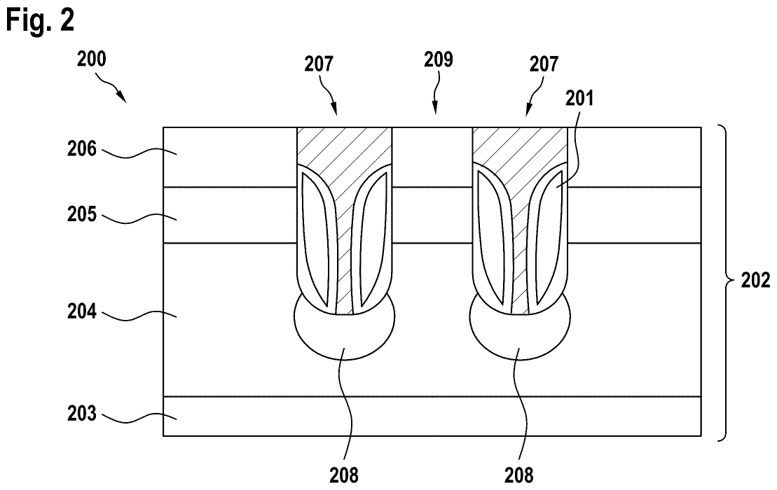

FIG. 2 shows a power FinFET 200 with two-part control electrodes 201 and a semiconductor body 202. The semiconductor body 202 comprises a first connection region 203, a drift layer 204, a channel region 205 and a second connection region 206. The drift layer 204 is arranged on the first connection region 203, wherein a semiconductor substrate and a buffer layer, which are not shown in FIG. 2, are arranged between the first connection region 203 and the drift layer 204. The channel region 205 is arranged on the drift layer 204, and the second connection region 206 is arranged on the channel region. The first connection region 203 acts as a drain terminal, and the second connection region 206 acts as a source terminal. The drift layer 204 is n-doped, and the channel region 205 is p-doped. Trenches 207 extend from the second connection region 206 into the drift layer 204. A shielding region 208 is arranged below each trench 207, wherein the shielding region 208 is p-doped. One two-part electrode 201 is in each case arranged within each trench 207, which two-part electrode is electrically insulated from the shielding region 208 by means of an oxide. The two-part control electrode 201 acts as a gate. Fins 209, which have a width of at most 500 nm, are arranged between the trenches 207. The semiconductor body 202 comprises a semiconductor material with a wide band gap, e.g., SiC or GaN.

The power FinFET is used in DC/DC converters and inverters of an electric drive train of electric or hybrid vehicles, and in vehicle chargers.

1-6. (canceled)

7. A method for producing a power FinFET with two-part control electrodes, wherein the power FinFET includes a semiconductor body, which includes a first connection region, a drift layer, a channel region, and a second connection region, wherein the drift layer is arranged on the first connection region, the channel region is arranged on the drift layer, and the second connection region is arranged on the drift layer, the method comprising the following steps:
producing trenches which extend from the second connection region into the drift layer, wherein the trenches are arranged substantially in parallel with one another;
producing shielding regions below the trenches by an implantation process, so that a shielding region is arranged below each trench;
widening the trenches using at least one etching process, so that fins are formed between the trenches, wherein the fins have a width of less than 500 nm; and
producing the two-part control electrodes, which are arranged within the trenches, so that a respective two-part control electrode is arranged within each trench, wherein the respective two-part control electrode is electrically insulated from the shielding region below the trench.

8. The method according to claim 7, wherein the shielding regions are produced by an implantation process which has an implantation energy of 30 to 2700 keV.

9. A power FinFET with two-part control electrodes, comprising:
a semiconductor body which includes a first connection region, a drift layer being arranged on the first connection region, a channel region being arranged on the drift layer, and a second connection region being arranged on the channel region, wherein trenches extend from the second connection region into the drift layer, and a shielding region is arranged below each of the trenches, wherein a respective two-part control electrode is arranged within each trench, the respective two-part control electrode being electrically insulated from the shielding region below the trench, wherein fins are arranged between the trenches, and wherein the fins have a width of less than 500 nm.

10. The power FinFET according to claim 9, wherein the shielding region has a doping concentration of at least 1E18/cm³.

11. The power FinFET according to claim 9, wherein the semiconductor body includes SiC.

12. The power FinFET according to claim 9, wherein the semiconductor body includes GaN.
